(19) United States
(12) Patent Application Publication
(10) Pub. No.: US 2015/0037731 A1
(43) Pub. Date: Feb. 5, 2015

(54) DRAWING APPARATUS AND ARTICLE MANUFACTURING METHOD

(71) Applicant: CANON KABUSHIKI KAISHA, Tokyo (JP)

(72) Inventor: Kentaro SANO, Utsunomiya-shi (JP)

(21) Appl. No.: 14/335,314

(22) Filed: Jul. 18, 2014

(30) Foreign Application Priority Data
Jul. 30, 2013 (JP) 2013-158268

(51) Int. Cl. H01J 37/12; G03G 9/00; H01J 37/147

(52) U.S. Cl. CPC H01J 37/12; H01J 37/147; G03G 9/00; H01J 2237/002; H01J 2237/30472
USPC 430/126.2; 250/396 R

(57) ABSTRACT

A drawing apparatus for performing drawing on a substrate includes: a decelerating electrostatic lens configured to decelerate a charged particle beam emitted by a charged particle source; a division unit having a plurality of apertures and configured to divide the charged particle beam decelerated by the decelerating electrostatic lens into a plurality of charged particle beams; and an accelerating electrostatic lens configured to accelerate the plurality of charged particle beams divided by the division unit.

### BACKGROUND OF THE INVENTION

1. Field of the Invention

The present invention relates to a drawing apparatus and an article manufacturing method.

2. Description of the Related Art

As a drawing apparatus, there is known a so-called multicolumn drawing apparatus including a charged particle optical system (column) for each charged particle beam (Japanese Patent Laid-Open No. 09-007538). Such a drawing apparatus has no crossover where a plurality of charged particle beams converge because charged particle optical systems individually exist for charged particle beams. Since the influence of the space-charge effect (Coulomb effect) is small, the multicolumn drawing apparatus is advantageous in increasing the number of charged particle beams and thus increasing the exposure current (that is, throughput) at the time of drawing.

In the multicolumn drawing apparatus, the Coulomb effect is no obstacle when increasing the number of charged particle beams. In fact, there is a limitation in increasing the number of columns, and it is difficult to infinitely arrange columns in an array and infinitely increase throughput. A constraint condition for a multicolumn array is, for example, an aberration caused by an increase in the angle of view of an illumination system. In the multicolumn array, generally, charged particle beams are collimated at once by a collimator lens or the like. For this reason, the larger the angle of view is, the larger the aberration is. This particularly affects the characteristics of the charged particle beams in columns outside the angle of view.

Hence, for example, the constraint of the illumination system places a constraint on the multicolumn array region (the illumination area of the illumination system). It is also difficult to infinitely make the columns and the array pitch small when manufacturing properties, aberration characteristics of a lens array, and the like are taken into consideration. For these reasons, when the constraints of the multicolumn array region and the multicolumn array pitch are determined to some extent, the number of arrayable columns is roughly determined. The exposure current that exposes a substrate is given by the product of the exposure current per column and the number of columns, as a matter of course. Since the exposure current (=throughput) of the multicolumn drawing apparatus is determined in the above-described way, it can be appreciated that the exposure current can be increased by, for example, increasing the exposure current amount per column or improving the aberrations and the like of the illumination system and thus making the multicolumn arrayable region large.

As a technique of increasing the exposure current per column, there is known an arrangement that provides apertures configured to further divide charged particle beams on the column basis and makes a plurality of charged particle beams enter each projection lens of the multicolumn (European Patent Publication No. 2301059). FIG. 8 shows the arrangement of a drawing apparatus described in European Patent Publication No. 2301059. As shown in FIG. 8, an electron beam diverging from an electron source 107 is substantially collimated by a collimator lens 109 and divided by a first aperture array 112 on the column basis. Each electron beam is further divided into a plurality of electron beams on the column basis by a second aperture array 116. The electron beams further divided on the column basis by the second aperture array are reduced and projected by the projection lens of the corresponding column. When the images of a plurality of electron beams are formed for each column of the multicolumn, as in this arrangement, the exposure current amount per column can be increased as compared to a system that causes only one electron beam to form an image for each column of the multicolumn. This can further increase the exposure current.

A technique of reducing aberrations caused by an increase in the angle of view of the illumination system is disclosed in, for example, patent literature 3. In the arrangement described in patent literature 3, a division unit such as an aperture array configured to divide a charged particle beam into a plurality of charged particle beams and a converging lens array are provided at the preceding stage of a collimator lens, thereby forming the images of the charged particle beams at the front principal plane position in the collimator lens. The technique disclosed in patent literature 3 can reduce chromatic aberrations caused by an increase in the angle of view of the illumination system by making the refracting effect of the collimator lens act at the imaging position. Hence, in a technique disclosed in Japanese Patent No. 4484868, the allowable illumination area extends, and the exposure current can be expected to be increased by extending the multicolumn arrayable region.

However, when the exposure current is increased to obtain high throughput, the amount of the current that enters the charged particle beam division unit configured to generate the plurality of charged particle beams also increases. In general, the energy of the charged particle beam that enters the division unit mostly changes to heat. For this reason, when increasing the exposure current to obtain high throughput, heat input to the division unit which can increase along with the increase in the exposure current poses a problem.

When increasing the exposure current by, for example, the method of European Patent Publication No. 2301059, a second aperture array configured to further divide each charged particle beam into a plurality of electron beams on the column basis is added, and therefore, the aperture ratio of the entire electron optical system generally lowers. This means that the amount of a current (that is, the amount of heat) that enters the division unit (aperture array) configured to divide electron beams increases. When reducing chromatic aberrations of the illumination system by the method of Japanese Patent No. 4484868, the charged particle beam division unit needs to be provided at the preceding stage (a position close to the charged particle source) of the collimator lens. This raises the incident current density (heat input density) in the division unit.

The above-described increase in the heat input amount (or heat input density) caused by an increase in the number of multibeams (exposure current or illumination area) leads to deformation by thermal expansion of the division unit and affects the electron optical system. In addition, radiant heat from the division unit and heat transfer via the support portion of the division unit may generate a heat load on the entire drawing apparatus.

### SUMMARY OF THE INVENTION

The present invention provides a drawing apparatus advantageous in terms of a heat load.

The present invention provide a drawing apparatus for performing drawing on a substrate, the apparatus comprising: a decelerating electrostatic lens configured to decelerate a charged particle beam emitted by a charged particle source; a division unit having a plurality of apertures and configured to divide the charged particle beam decelerated by the decelerating electrostatic lens into a plurality of charged particle beams; and an accelerating electrostatic lens configured to accelerate the plurality of charged particle beams divided by the division unit.

Further features of the present invention will become apparent from the following description of exemplary embodiments with reference to the attached drawings.

### BRIEF DESCRIPTION OF THE DRAWINGS

FIG. 1 is a view showing a drawing apparatus according to the first embodiment;

FIGS. 2A and 2B are views showing an on-axis electric potential on the periphery of a first division unit according to the first embodiment;

FIG. 3 is a view showing a drawing apparatus according to the second embodiment;

FIGS. 4A and 4B are views showing an on-axis electric potential on the periphery of a first division unit according to the second embodiment;

FIGS. 5A and 5B are views showing the aperture position relationship between the first division unit, an illumination area defining unit, and a second division unit according to the second embodiment;

FIG. 6 is a view showing a drawing apparatus according to the third embodiment;

FIGS. 7A and 7B are views showing an on-axis electric potential on the periphery of a first division unit according to the third embodiment; and

FIG. 8 is a view showing a conventional drawing apparatus.

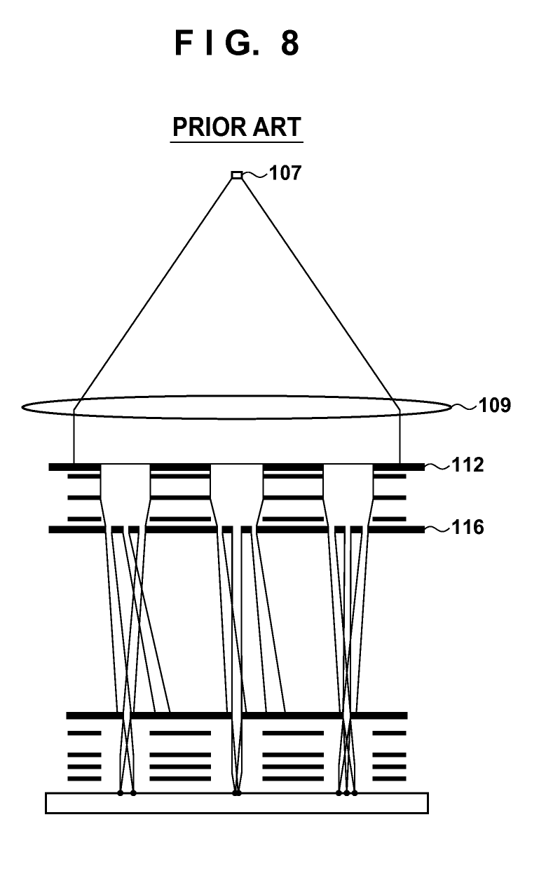

### DESCRIPTION OF THE EMBODIMENTS

The embodiments of the present invention will now be described in detail with reference to the accompanying drawings. Note that the same reference numerals denote the same members in principle throughout the drawings for explaining the embodiments, and a repetitive description thereof will be omitted. Note that in the embodiments, an example in which an electron beam is used as a charged particle beam will be described. However, the present invention is not limited to a drawing apparatus using an electron beam and is also applicable to other charged particle beam drawing apparatuses using, for example, an ion beam.

### First Embodiment

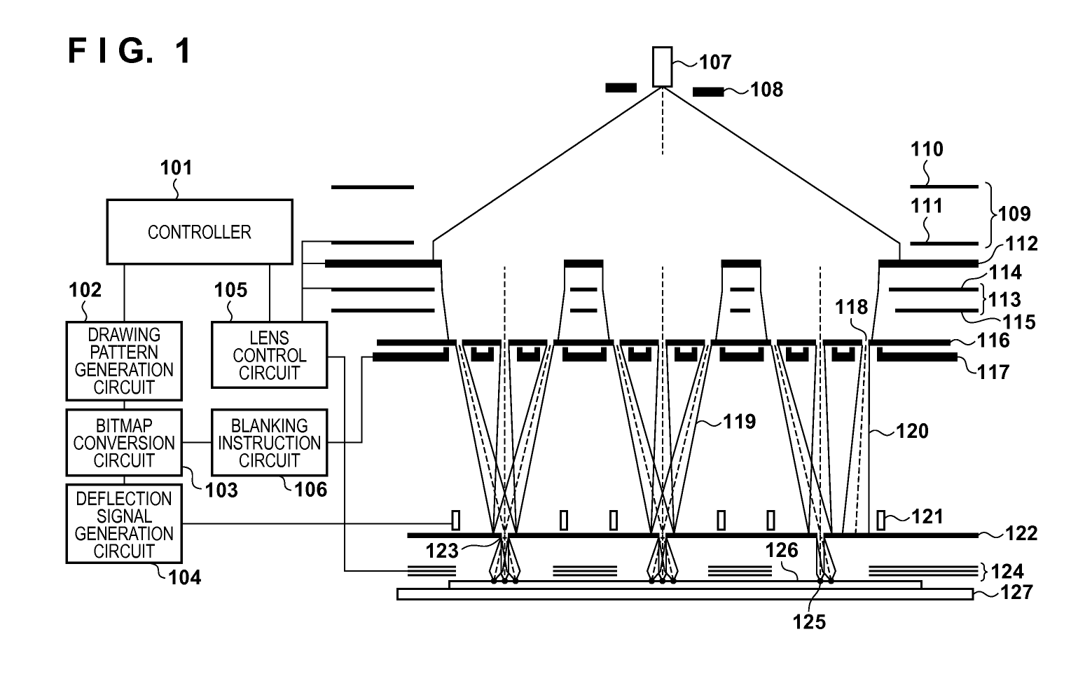

FIG. 1 is a view showing the arrangement of a drawing apparatus according to the first embodiment, which performs drawing on a substrate with a plurality of electron beams. The drawing apparatus according to this embodiment is a so-called multicolumn drawing apparatus including a projection unit for each electron beam. Referring to FIG. 1, an electron beam is extracted from a cathode electrode 107 by an anode electrode 108 and emitted. These electrodes can form a so-called thermionic electron source (charged particle source) including LaB₆ or BaO/W (dispenser cathode) in an electron emitting portion. The electron beam emitted by the electron source is changed to an almost parallel electron beam by a collimator lens 109 and enters a first division unit 112.

The collimator lens 109 is a so-called bipotential lens (decelerating electrostatic lens) in which a collimator lower electrode 111 is set to a negative electric potential with respect to a collimator upper electrode 110. When such a bipotential lens in which the collimator lower electrode 111 has a negative electric potential is employed as the collimator lens 109, the electron beam passing through the collimator lens 109 is decelerated in accordance with the electric potential of the collimator lower electrode 111. In this embodiment, the collimator lens 109 has a two-electrode structure. However, a multistage lens including three or more electrodes is also usable as long as it substantially has the effect of decelerating an electron beam.

The electron beam decelerated by the collimator lens 109 enters the first division unit 112 and is divided into a plurality of electron beams. The first division unit 112 is set to a negative electric potential with respect to a wafer (substrate) 126 and set to a negative electric potential with respect to, for example, the anode electrode 108 that has the most positive electric potential out of the electrode potentials constituting the electron optical system on the upper side (electron source side) of the first division unit 112 along the optical axis. For example, the electric potential of the first division unit 112 is set to match (equal) the electric potential of the lower electrode (electrode close to the division unit) 111 of the collimator lens 109. “Electric potentials match” includes not only a case where the electric potentials completely match but also a case where the electric potentials mismatch, because of a manufacturing error or a positioning error, within an allowable range set based on an accuracy required of the drawing apparatus. This also applies to the expression “match” in the following description.

When the electric potential of the first division unit 112 is lowered, the energy of the electron beam that enters the first division unit 112 can be reduced, and heat input to the first division unit 112 can be reduced. The above-described arrangement can be implemented by controlling the decelerating electric field (by the collimator lens 109) of the preceding stage of the first division unit and a voltage applied to the first division unit 112.

The plurality of electron beams generated by the first division unit 112 are converged by a condenser lens array 113. The condenser lens array 113 can be a so-called bipotential lens array (accelerating electrostatic lens) in which an upper electrode 114 is set to a negative electric potential with respect to a lower electrode 115. When the condenser lens array 113 of a bipotential type is used, the plurality of electron beams are accelerated when passing through the condenser lens array 113. For example, the electric potential of the upper electrode (electrode close to the division unit) 114 of the condenser lens array 113 is set to match (equal) the electric potential of the first division unit 112. The electric potential of the lower electrode (electrode close to the substrate) 115 is set to match (equal) the electric potential of the wafer 126 (the electric potential of the substrate). With this structure, for example, the condenser lens array 113 not only individually converges the plurality of electron beams but also accelerates them from the electric potential of the first division unit 112 to an electric potential close to that of the wafer 126.

The power of each lens of the condenser lens array 113 is set so as to converge the plurality of electron beams on a stop aperture array 122 on the rear side. Immediately after passing through the condenser lens array 113, each of the plurality of electron beams (multi-electron beams) is further divided into a plurality of electron beams, that is, submulti-electron beams (at least some of the multi-electron beams) by a second division unit 116. FIG. 1 shows a state in which each of the multi-electron beams is divided into 3×3=9 submulti-electron beams.

Since the power of each lens of the condenser lens array 113 is set as described above, the submulti-electron beams are converged on the stop aperture array 122. The stop aperture array 122 has one aperture for a submulti-electron beam. Apertures 123 of the stop aperture array 122 are arrayed such that each aperture matches the aperture at the center of a corresponding 3×3 sub-aperture array of the second division unit 116.

A blanker array 117 is provided immediately under the second division unit 116. A blanking operation of each electron beam can be performed by individual deflection. To blank (block) an electron beam, a voltage is applied to a corresponding electrode pair of the blanker array 117. The electron beam is thus blanked by stop aperture array 122. An “electron beam 120” shown in FIG. 1 indicates an electron beam deflected (blanked) by the blanker array 117.

The submulti-electron beams (at least some of the submulti-electron beams) passed through the stop aperture array 122 are converged by a projection lens array 124 and form images on the surface of the wafer 126. The second division unit 116 is positioned on the object plane of the projection lens array 124. Each 3×3 aperture pattern of the second division unit 116 is reduced and projected onto the surface of the wafer 126 by a corresponding lens of the projection lens array 124. For example, the aperture diameter of the second division unit 116 is set to 2.5 μm, and the projection magnification of the projection lens array 124 is set to 1/100. As a result, an image having a diameter of 25 nm is formed on the surface of the wafer 126. Note that the stop aperture array 122 is positioned on the front focal plane of the projection lens array 124 and serves as an NA stop for the projection lens array 124. That is, the stop aperture array 122 has not only a function of blocking an electron beam blanked by the blanker array 117 but also a function of defining the convergence half angle of an electron beam that passes through the projection lens array 124.

A deflector array 121 is positioned near the stop aperture array 122, and the submulti-electron beams can be deflected (scanned). The deflector array 121 is driven by, for example, a common applied voltage, and its electrode structure can be formed by interdigital counter electrodes. During drawing, a stage 127 continuously moves the wafer 126 in the X direction, and the deflector array 121 deflects electron beams 125 on the wafer surface in the Y direction based on a real-time measurement result by a laser measuring device. In addition, the blanker array 117 individually on/off-controls the beams in accordance with the drawing pattern. The drawing apparatus can thus draw a desired pattern on the surface of the wafer 126 at a high speed.

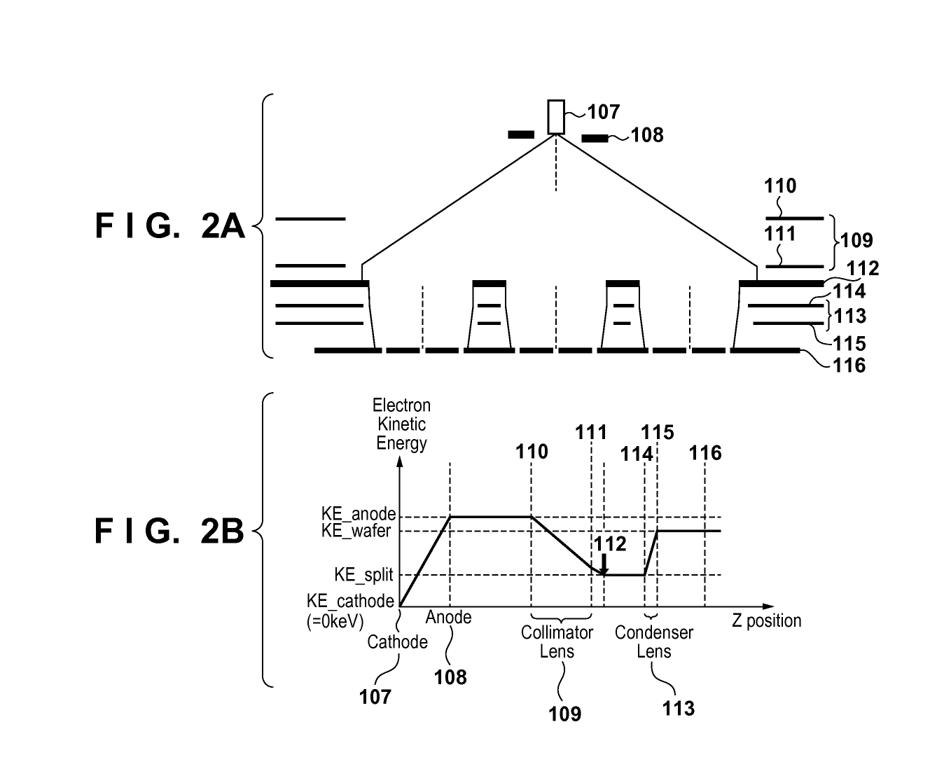

FIGS. 2A and 2B are views showing the kinetic energy of an electron beam on the periphery of the first division unit 112 of the drawing apparatus according to the first embodiment. FIG. 2A is a view showing the portion from the electron source to the second division unit 116 out of the drawing apparatus according to the first embodiment. FIG. 2B is a graph schematically showing the kinetic energy of an electron beam from the electron source to the second division unit 116.

As shown in FIG. 2B, between the cathode electrode 107 and the anode electrode 108, the anode electrode 108 temporarily accelerates the electron beam up to KE_anode. After that, the accelerated electron beam is decelerated by the collimator lens 109 to suppress heat input to the first division unit 112 that divides the electron beam. The first division unit 112 is set to a negative electric potential with respect to the GND potential (the electric potential of the substrate) so that the decelerated electron beam enters the first division unit 112 without accelerating. Note that when not an electron beam but an ion beam having positive charges is used as a charged particle beam, the first division unit 112 is set to a positive electric potential with respect to the GND potential (the electric potential of the substrate). Immediately after being divided by the first division unit 112, the electron beams are accelerated by the condenser lens array 113 up to KE_wafer that is the kinetic energy of the electron beams on the wafer 126. The electron beams thus reach the wafer 126 with a desired kinetic energy.

As described above, the electron beam is decelerated and accelerated before and after the electron beam division unit, thereby lowering the kinetic energy of the electron beam only on the periphery of the division unit. To solve only heat input to the division unit, it should only be necessary to lower the kinetic energy of the electron beam in the entire electron optical system. Normally, however, the kinetic energy of the electron beam is not lowered in the entire electron optical system due to the following reasons.

First, weakening the effect of the electric field extracted by the anode electrode 108 in the electron beam extraction portion from the cathode electrode 107 to the anode electrode 108 may cause a decrease in the luminance or extraction current value. It is therefore difficult to largely reduce the energy of the electron beam in the electron beam extraction portion. In the projection system near the wafer 126, the larger the decrease in the kinetic energy of the electron beam is, the larger the influence of chromatic aberrations is. For this reason, when the kinetic energy of the electron beam in the projection lens array 124 is lowered, the resolving power (resolution) lowers. Even as for the electric potential of the wafer 126, the lower the kinetic energy of the electron beam reaching the wafer 126 is, the larger the spread of electrons caused by forward scattering in the resist applied to the wafer surface is. Since this also affects the resolving power, it is difficult to freely lower the energy. Furthermore, if the kinetic energy of the electron beam in the entire electron optical system is lowered, the influence of blur (Coulomb effect) caused by Coulomb repulsion or magnetic field disturbance in the entire electron optical system increases.

For these reasons, in this embodiment, placing focus on the problem of heat input to the electron beam division unit, the kinetic energy of the electron beam is lowered only on the periphery of the division unit, thereby decreasing the heat input amount to the division unit while maintaining the electron optical performance of the drawing apparatus. To do this, in this embodiment, a decelerating bipotential lens and an accelerating bipotential lens are positioned to be close to each other on the upper and lower sides of the electron beam division unit. As can be seen from this embodiment, each of the upper and lower bipotential lenses has a function as a lens (collimator lens and condenser lens). The primarily required lens effect function and the accelerating/decelerating function for suppressing heat input to the electron beam division unit are imparted to each lens in the above-described way, thereby maintaining the above-described electron optical performance and simultaneously implementing downsizing of the electron optical system.

To make the deceleration region (the region where the kinetic energy of the electron beam is low) as short as possible, the division unit may be positioned so as to be immersed in the electric fields of the upper and lower bipotential lenses. At this time, voltages to be applied to the lens electrodes are set considering that immersion of the division unit in the lens electric fields slightly weakens the powers of the bipotential lenses.

Assume that the kinetic energy of the electron beam shown in FIG. 2B changes to, for example, KE_cathode=0 keV, KE_anode=6 keV, KE_split=2 keV, and KE_wafer=5 keV. As compared to a case where KE_split=5 keV (electric potential equal to the wafer potential), the kinetic energy of the electron beam that enters the first division unit 112 decreases from 5 keV to 2 keV. Hence, the heat input amount decreases to 2/5.

### Second Embodiment

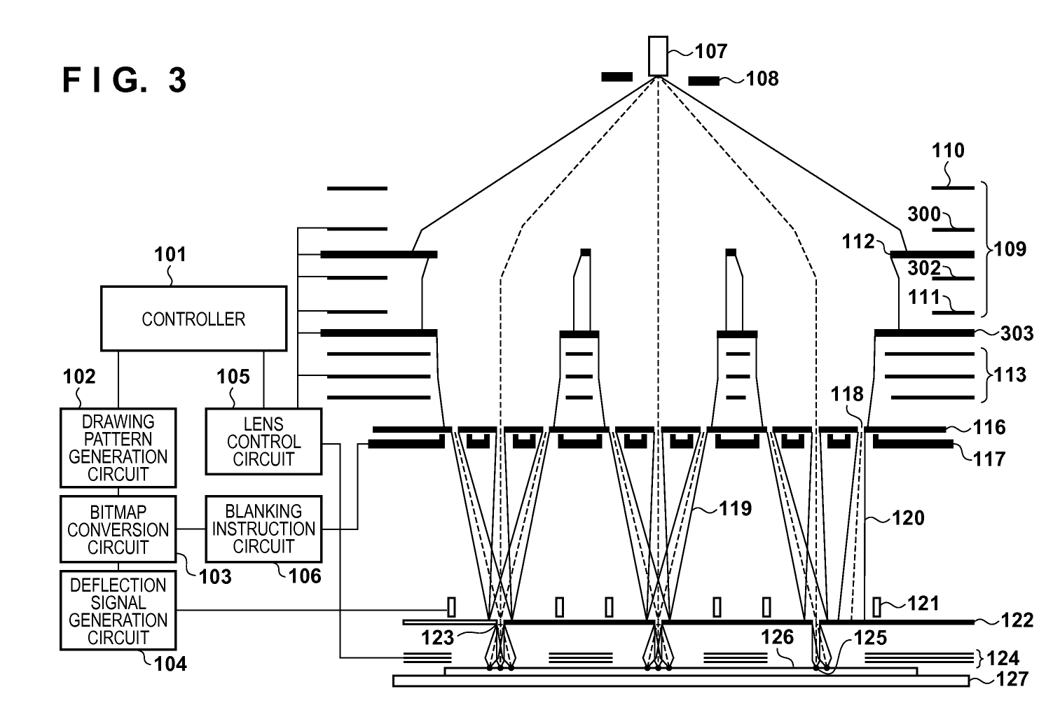

FIG. 3 is a view showing the arrangement of a drawing apparatus according to the second embodiment, which performs drawing on a substrate with a plurality of charged particle beams. As a characteristic feature of the second embodiment, an electron beam division unit is positioned in a region of a collimator lens 109 where the internal electric potential is low, thereby reducing heat input to the division unit. In the second embodiment, the arrangement on the lower side (wafer side) of a second division unit 116 along the optical axis is exactly the same as in the first embodiment, and a description thereof will be omitted.

An electron beam diverging from an electron source 107 is collimated by the collimator lens 109. The collimator lens 109 is formed from an upper electrode 110, a first intermediate electrode 300, a second intermediate electrode 302, and a lower electrode 111. Negative voltages are applied to the first intermediate electrode 300 and the second intermediate electrode 302. A first division unit 112 configured to divide the electron beam is positioned between the first intermediate electrode 300 and the second intermediate electrode 302 of the collimator lens 109. The first intermediate electrode 300, the first division unit 112, and the second intermediate electrode 302 can be set to, for example, negative electric potentials that match each other. However, the electric potential of the two intermediate electrodes 300 and 302 may be changed from the electric potential of the first division unit 112. The collimator lens 109 causes the converging effect to act near the first intermediate electrode 300. The electron beam is divided into a plurality of electron beams (multi-electron beams) by the first division unit 112. After that, the collimator lens 109 causes the converging effect to act again near the second intermediate electrode 302, thereby collimating the electron beams. Out of the collimator lens 109, the upper electrode 110 and the first intermediate electrode 300 on the upstream side of the first division unit 112 form a decelerating electrostatic lens configured to decelerate the electron beam. On the other hand, the second intermediate electrode 302 and the lower electrode 111 on the downstream side of the first division unit 112 form an accelerating electrostatic lens configured to accelerate the electron beam.

An illumination area defining unit 303 is provided at the subsequent stage of the collimator lens 109. The illumination area defining unit 303 has an aperture diameter smaller than the diameter of each of the rays of the plurality of electron beams divided by the first division unit 112. The illumination area defining unit 303 can redefine the positions and diameters of the rays of the plurality of electron beams. Redefining the rays using the aperture arrays of two stages aims at increasing the position accuracy of the rays entering the second division unit 116. As the characteristic features of the second embodiment, the lens effect of the collimator lens 109 acts even after the first division unit 112 divides the electron beam, and the distance between the first division unit 112 and the second division unit 116 becomes long. Hence, if the rays are defined only by the first division unit 112, it may be difficult to cause the rays accurately enter regions on the second division unit 116, which should be irradiated with them.

To avoid this problem, in the second embodiment, aperture arrays of two stages are used, and each aperture of the first division unit 112 is made larger than that of the illumination area defining unit 303, thereby ensuring the margin. When the illumination area defining unit 303 redefines the rays in this way, they can accurately enter the second division unit 116. The electric potential of the illumination area defining unit 303 is set so as to match, for example, the electric potential (ground potential) of a wafer (substrate) 126. The amount of electrons (amount of a current) entering the illumination area defining unit 303 is generally smaller than the electron amount to the first division unit 112. Hence, the above-described arrangement that sets the illumination area defining unit 303 not to a negative electric potential but to the ground potential can be employed.

A condenser lens 113 is provided on the lower side (substrate side) of the illumination area defining unit 303 along the optical axis. The function of the condenser lens 113 is the same as in the first embodiment. The power of the condenser lens 113 is adjusted so as to converge 3×3 electron beams (submulti-electron beams) onto an aperture of a stop aperture array 122.

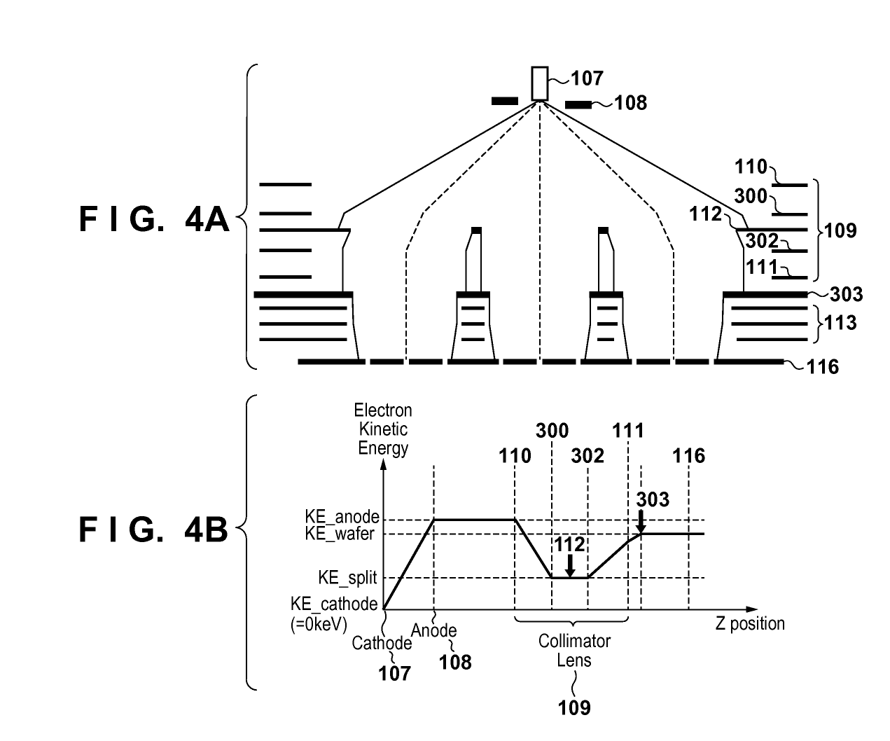

FIGS. 4A and 4B are views showing the kinetic energy of an electron beam on the periphery of the first division unit 112 of the drawing apparatus according to the second embodiment. FIG. 4A is a view showing the portion from the electron source 107 to the second division unit 116 out of the arrangement according to the second embodiment. FIG. 4B is a graph schematically showing the kinetic energy of an electron beam from the electron source 107 to the second division unit 116.

As shown in FIG. 4B, when the first division unit 112 is positioned in the intermediate electrode portion of the collimator lens 109, the kinetic energy of the electron beam in the first division unit 112 can be lowered, and heat input to the first division unit 112 can be reduced. In addition, “instead of simply lowering the kinetic energy of the electron beam in the entire electron optical system, the kinetic energy is lowered only on the periphery of the electron beam division unit, thereby reducing heat input while suppressing an optical influence”, as can be seen.

Assume that the kinetic energy of the electron beam shown in FIG. 4B changes to, for example, KE_cathode=0 keV, KE_anode=6 keV, KE_AA=2 keV, and KE_wafer=5 keV. As compared to a case where KE_AA=5 keV (electric potential equal to the wafer potential), the kinetic energy of the electron beam that enters the first division unit 112 decreases from 5 keV to 2 keV. Hence, the heat input amount decreases to 2/5.

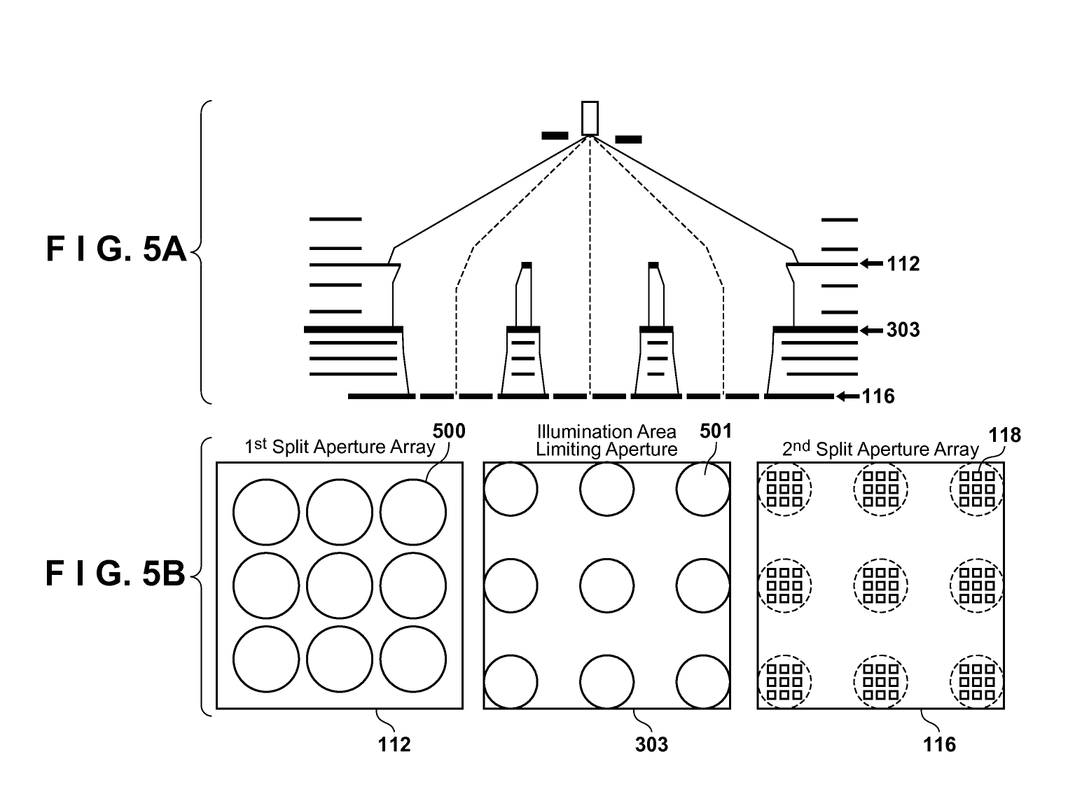

FIGS. 5A and 5B are views showing the aperture position relationship between the first division unit 112, the illumination area defining unit 303, and the second division unit 116 according to the second embodiment. FIG. 5A is a view showing the portion from the electron source 107 to the second division unit 116 out of the arrangement according to the second embodiment. Arrows are added to the positioning points of the aperture arrays. FIG. 5B is a view illustrating examples of apertures of the first division unit 112, the illumination area defining unit 303, and the second division unit 116 from the left side. The three kinds of aperture arrays will be described below mainly with reference to FIG. 5B.

As described above, the converging effect of the collimator lens 109 acts even near the second intermediate electrode 302 at the subsequent stage after the first division unit 112 serving as an aperture array configured to divide an electron beam divides an electron beam into a plurality of electron beams (multi-electron beams). Taking this into consideration, the plurality of electron beams immediately after passing through the first division unit 112 are not almost parallel electron beams. They become almost parallel electron beams only after passing through the second intermediate electrode 302 at the subsequent stage.

This is reflected by the array pitch of apertures 500 of the first division unit 112 shown in FIG. 5B, which is narrower than the array pitch of apertures 501 of the illumination area defining unit 303. That is, the plurality of electron beams diverge to some extent after they pass through the first division unit 112 until the converging effect of the second intermediate electrode 302 at the subsequent stage of the collimator lens acts on the electron beams. For this reason, the pitch of the apertures 500 of the first division unit 112 is made narrower than the pitch of the apertures 501 of the illumination area defining unit 303 at the subsequent stage. As for the aperture diameter, the diameter of the apertures 500 of the first division unit 112 is larger than that of the apertures 501 of the illumination area defining unit 303, as described above. With this margin, an effect of relaxing the accuracy required for the parallel eccentricity between the first division unit 112 and the illumination area defining unit 303 and an effect of lowering the degree of difficulty in adjusting the power of the collimator lens can be expected. The array of the apertures 501 of the illumination area defining unit 303 corresponds to the illumination areas of the second division unit 116 at the subsequent stage. Hence, as shown on the right side of FIG. 5B, the array of the apertures 501 of the illumination area defining unit 303 is determined such that the center of the pattern (indicated by a 3×3 pattern in the example) of the second division unit 116 is irradiated with an electron beam.

The characteristic features and advantages of the second embodiment as compared to the first embodiment will be described. As a characteristic feature of the second embodiment, the first division unit 112 is positioned in the collimator lens 109, and the illumination area defining unit 303 configured to define the rays of electron beams is separately positioned at the subsequent stage. With this arrangement, for example, when a current mostly enters the first division unit 112, and only a small amount of the current enters the illumination area defining unit 303 configured to define rays at the subsequent stage, the electric potential of the illumination area defining unit 303 configured to define rays need not be lowered. In addition, since the illumination areas on the second division unit 116 are determined by the illumination area defining unit 303 configured to define rays, as described above, the illumination area defining unit 303 configured to define rays is required to have a high aperture position accuracy. The apertures of the first division unit 112 may be shifted within a margin with respect to the apertures of the illumination area defining unit 303.

Hence, when providing a cooling mechanism such as a water cooling mechanism in an aperture array is considered, an arrangement that water-cools only the illumination area defining unit 303 for which the required aperture position accuracy is high is possible. In the arrangement that water-cools only the illumination area defining unit 303, a high voltage portion need not be cooled. This is a characteristic feature that is not available in the first embodiment. More specifically, according to the second embodiment, an arrangement that provides a cooling mechanism in the illumination area defining unit 303 set to the ground potential at the subsequent stage is usable without a problem even when it is difficult to implement a cooling mechanism such as a water cooling mechanism for a high voltage portion. The arrangement of the first embodiment that uses a simple two-stage aperture array structure cannot obtain this advantage because both of the aperture arrays of the two stages are set to negative voltages.

### Third Embodiment

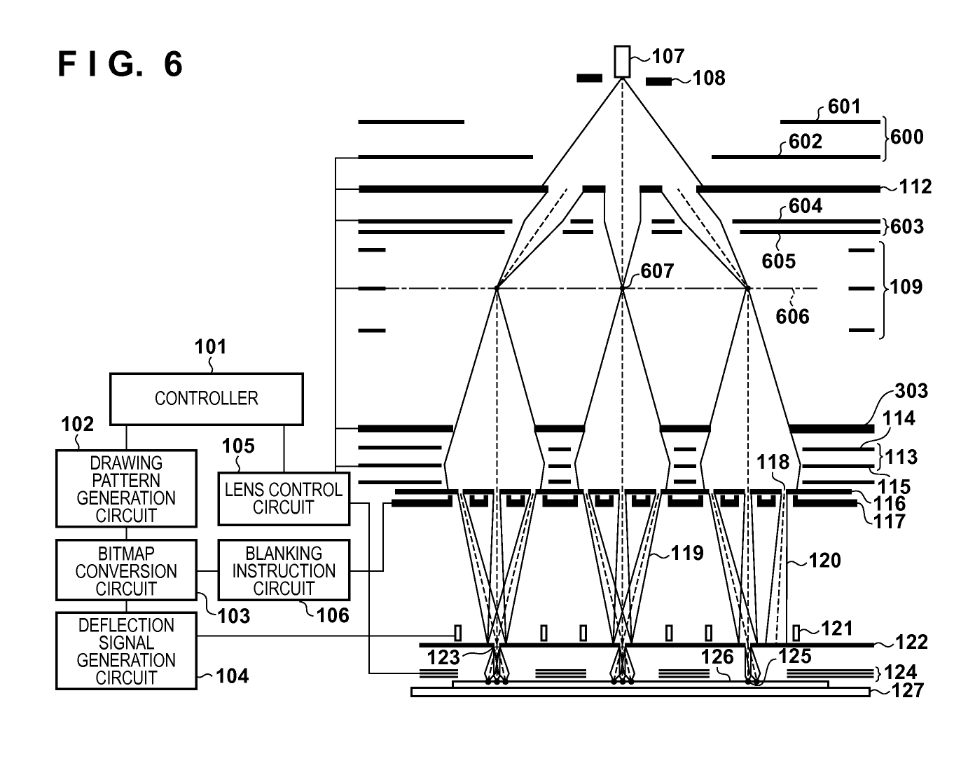

FIG. 6 is a view showing the arrangement of a drawing apparatus according to the third embodiment, which performs drawing on a substrate with a plurality of charged particle beams. As a characteristic feature of the third embodiment, in an arrangement using the technique described in Japanese Patent No. 4484868 in which an electron beam division unit is positioned at the preceding stage of a collimator lens 109, a decelerating electrostatic lens is separately provided at the preceding stage of the division unit, thereby lowering the electric potential of the division unit and reducing heat input to the division unit. The arrangement according to the third embodiment on the lower side (wafer side) of a second division unit 116 along the optical axis is exactly the same as in the first and second embodiments, and a description thereof will be omitted.

An electron beam diverging from an electron source 107 is decelerated to a desired electric potential by a decelerating electrostatic lens 600, and then enters a first division unit 112 positioned at the preceding stage of the collimator lens 109. The decelerating electrostatic lens 600 can be a decelerating bipotential lens in which, for example, the electric potential of a lower electrode 602 is lower than that of an upper electrode 601. When the electron beam is temporarily decelerated by the decelerating electrostatic lens 600 and then enters the first division unit 112, the amount of heat input to the first division unit 112 can be reduced.

A pre-converging lens array 603 is provided at the lower stage of the first division unit 112. The pre-converging lens array 603 is a lens array that causes a converging effect to individually act on a plurality of divided electron beams, and is formed from an accelerating bipotential lens array in which, for example, the electric potential of an upper electrode 604 is lower than that of a lower electrode 605. The pre-converging lens array 603 forms an accelerating electrostatic lens configured to accelerate the electron beams. When an accelerating bipotential lens is used as the pre-converging lens array 603, the electron beams passing through the pre-converging lens array 603 are not only individually converged but also accelerated. For example, the electric potential of the upper electrode 604 of the pre-converging lens array 603 can be set to match the electric potential of the first division unit 112, and the electric potential of the lower electrode 605 can be set to match the electric potential of a wafer (substrate) 126.

The collimator lens 109 is provided on the lower side (substrate side) of the pre-converging lens array 603 along the optical axis. The power of the collimator lens 109 is adjusted to almost collimate the principal rays of a plurality of diverging electron beams. The power of the pre-converging lens array 603 is adjusted to cause the plurality of electron beams to spot near the front principal plane of the collimator lens 109. With this arrangement, chromatic aberrations of the illumination system can be reduced, as described in Japanese Patent No. 4484868.

An illumination area defining unit 303 is provided on the lower side (substrate side) of the collimator lens 109 along the optical axis and redefines the rays of the plurality of electron beams. Redefining the rays can produce the same effect as that of the illumination area defining unit 303 according to the second embodiment, that is, accurately define the illumination areas on the second division unit 116. Note that since the illumination area defining unit 303 is positioned due to the above-described reason, it may be removed from the arrangement if, for example, illumination on the second division unit 116 can sufficiently be guaranteed by definition of rays by the first division unit 112. The illumination area defining unit 303 is set to, for example, the ground potential considering that, for example, the amount of entering electrons (current amount) is smaller than that of the first division unit 112.

The plurality of electron beams that have passed through the illumination area defining unit 303 are individually converged by a condenser lens array 113 and then enter the second division unit 116. The function of the condenser lens array 113 is the same as in the other embodiments. The power of the condenser lens array 113 is adjusted so as to converge the electron beams (submulti-electron beams) further divided by the second division unit 116 onto the apertures of a stop aperture array 122 positioned on the lower side (substrate side) along the optical axis.

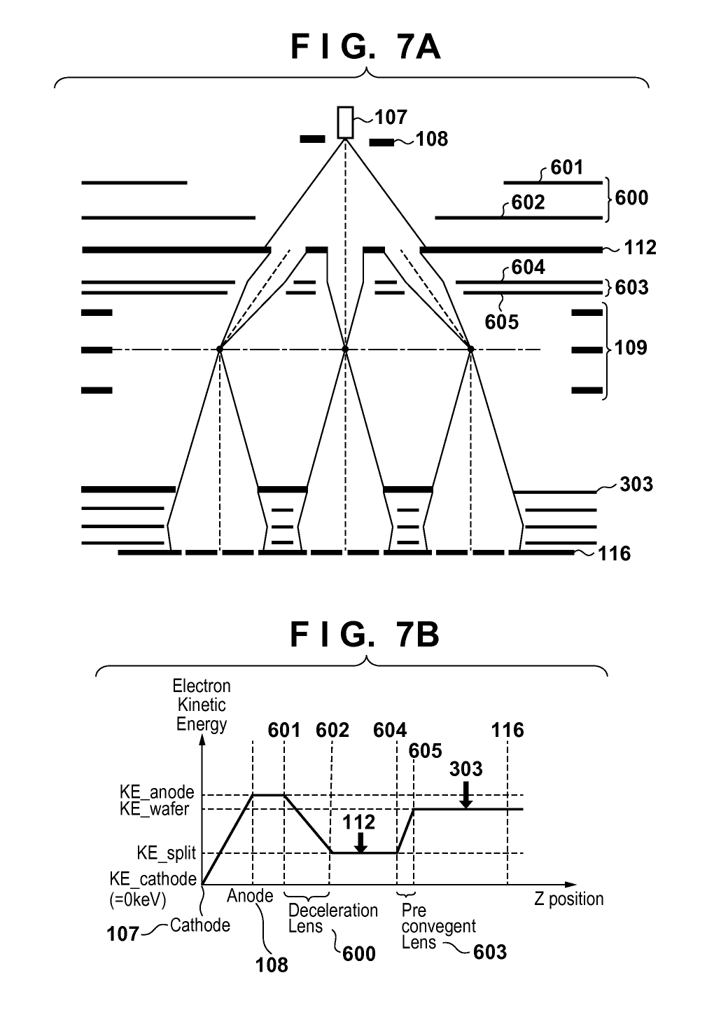

FIGS. 7A and 7B are views showing the kinetic energy of an electron beam on the periphery of an aperture array configured to divide the electron beam in the drawing apparatus according to the third embodiment. FIG. 7A is a view showing the portion from an electron source 107 to the second division unit 116 out of the arrangement according to the third embodiment. FIG. 7B is a graph schematically showing the kinetic energy of an electron beam from the electron source 107 to the second division unit 116. As in the other embodiments, the electron beams are decelerated and accelerated before and after the first division unit 112. This arrangement reduces heat input to the first division unit 112 without largely deteriorating the performance of the electron optical system. In the third embodiment, the decelerating portion is the decelerating electrostatic lens 600, and the accelerating portion is the pre-converging lens 603. The above-described arrangement relaxes the problem of heat input (density) to the electron beam division unit, which can be one of problems when employing the arrangement of patent literature 3.

Assume that the kinetic energy of the electron beam shown in FIG. 7B changes to, for example, KE_cathode=0 keV, KE_anode=6 keV, KE_AA=2 keV, and KE_wafer=5 keV. As compared to a case where KE_AA=5 keV (electric potential equal to the wafer potential), the kinetic energy of the electron beam that enters the first division unit 112 decreases from 5 keV to 2 keV. Hence, the heat input amount decreases to 2/5.

In the third embodiment, the pre-converging lens 603 that has a plurality of apertures and causes the lens effect to individually act on the plurality of electron beams divided by the first division unit 112 is used as the accelerating portion configured to accelerate the electron beams at the subsequent stage of the first division unit 112. However, the accelerating portion may be configured to have one aperture and cause the lens effect to act at once on the plurality of electron beams divided by the first division unit 112.

### Fourth Embodiment

An article manufacturing method according to this embodiment is suitable for manufacturing an article, for example, a microdevice such as a semiconductor device or an element having a fine structure. The manufacturing method can include a step of forming a latent image pattern on a photoresist applied to a substrate using the above-described drawing apparatus (a step of performing drawing on a substrate), and a step of developing the substrate on which the latent image pattern is formed in the above step. The manufacturing method can also include other known processes (for example, oxidation, deposition, vapor deposition, doping, planarization, etching, resist removal, dicing, bonding, and packaging). The article manufacturing method according to this embodiment is advantageous in at least one of the performance, quality, productivity, and production cost of the article, as compared to conventional methods.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-158268, filed Jul. 30, 2013, which is hereby incorporated by reference herein in its entirety.

What is claimed is:

1. A drawing apparatus for performing drawing on a substrate, the apparatus comprising:
a decelerating electrostatic lens configured to decelerate a charged particle beam emitted by a charged particle source;
a division unit having a plurality of apertures and configured to divide the charged particle beam decelerated by said decelerating electrostatic lens into a plurality of charged particle beams; and
an accelerating electrostatic lens configured to accelerate the plurality of charged particle beams divided by said division unit.

2. The apparatus according to claim 1, wherein when charges of the charged particle beams are negative, an electric potential of said division unit is lower than the electric potential of the substrate, and when the charges of the charged particle beams are positive, the electric potential of said division unit is higher than the electric potential of the substrate.

3. The apparatus according to claim 1, further comprising a projection lens array configured to project at least some of the plurality of charged particle beams divided by said division unit onto the substrate,
wherein said accelerating electrostatic lens is positioned between said division unit and said projection lens array.

4. The apparatus according to claim 1, wherein said decelerating electrostatic lens comprises a bipotential lens configured to collimate the charged particle beam emitted by the charged particle source.

5. The apparatus according to claim 1, wherein said decelerating electrostatic lens includes at least two electrodes, when charges of the charged particle beams are negative, an electric potential of the electrode close to said division unit is lower than the electric potential of the electrode close to the charged particle source, and when the charges of the charged particle beams are positive, the electric potential of the electrode close to said division unit is higher than the electric potential of the electrode close to the charged particle source.

6. The apparatus according to claim 1, wherein said accelerating electrostatic lens comprises a bipotential lens configured to converge the plurality of charged particle beams divided by said division unit.

7. The apparatus according to claim 1, wherein said accelerating electrostatic lens comprises a bipotential lens configured to collimate the plurality of charged particle beams divided by said division unit.

8. The apparatus according to claim 1, wherein said accelerating electrostatic lens includes at least two electrodes, when charges of the charged particle beams are negative, an electric potential of the electrode close to the substrate is higher than the electric potential of the electrode close to said division unit, and when the charges of the charged particle beams are positive, the electric potential of the electrode close to the substrate is lower than the electric potential of the electrode close to the division unit.

9. The apparatus according to claim 8, wherein in said accelerating electrostatic lens, the electric potential of the electrode close to said division unit equals the electric potential of said division unit, and the electric potential of the electrode close to the substrate equals the electric potential of the substrate.

10. The apparatus according to claim 1, wherein said decelerating electrostatic lens has one aperture and causes a lens effect to act on the charged particle beam emitted by the charged particle source.

11. The apparatus according to claim 1, wherein said accelerating electrostatic lens has a plurality of apertures and causes a lens effect to act on each of the plurality of charged particle beams divided by said division unit.

12. The apparatus according to claim 1, wherein said accelerating electrostatic lens has one aperture and causes a lens effect to act on the plurality of charged particle beams divided by said division unit.

13. A method of manufacturing an article, the method comprising:
performing drawing on a substrate using a drawing apparatus;
developing the substrate on which the drawing has been performed; and
processing the developed substrate to manufacture the article,
wherein the drawing apparatus includes:
a decelerating electrostatic lens configured to decelerate a charged particle beam emitted by a charged particle source;
a division unit having a plurality of apertures and configured to divide the charged particle beam decelerated by the decelerating electrostatic lens into a plurality of charged particle beams; and
an accelerating electrostatic lens configured to accelerate the plurality of charged particle beams divided by the division unit.
